(19) United States
(12) Patent Application Publication
(10) Pub. No.: US 2009/0184426 A1
(43) Pub. Date: Jul. 23, 2009

(54) CONTACT PLUGS OF SEMICONDUCTOR DEVICE AND METHOD FOR FORMING THE SAME

(75) Inventor: Yun Je CHOI, Seoul (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX SEMICONDUCTOR INC., Icheon-si (KR)

(21) Appl. No.: 12/163,329

(22) Filed: Jun. 27, 2008

(30) Foreign Application Priority Data
Jan. 23, 2008 (KR) 10-2008-0007023

(51) Int. Cl. H01L 21/44; H01L 23/48

(52) U.S. Cl. 257/773; 438/675; 257/E23.01; 257/E21.476

(57) ABSTRACT

The contact plugs of a semiconductor device includes first contact plugs having an elliptical sectional shape, and second contact plugs formed on the first contact plugs and having a circular sectional shape. The second contact plugs being configured to come in contact with the first contact plugs, thereby preventing voids from being formed.

### CROSS-REFERENCES TO RELATED APPLICATIONS

The present application claims priority to Korean patent application number 10-2008-0007023, filed on Jan. 23, 2008, which is incorporated by reference in its entirety.

### BACKGROUND OF THE INVENTION

The present invention relates to the contact plugs of a semiconductor device and a method for forming the same. More particularly, the present invention relates to the contact plugs of a semiconductor device, which can secure an alignment margin thereof, and a method for forming the same.

In a semiconductor device, in order to electrically connect a lower structure and an upper structure, contact plugs are used. For instance, considering that the plurality of gate lines formed on a semiconductor substrate constitute the lower structure and the metal lines formed in layers over the gate lines constitute the upper structure, the contact plugs electrically connect the gate lines and the metal lines. Junction areas are formed in the portions of the semiconductor substrate which are brought into contact with the lower portions of the gate lines. The contact plugs are formed between the junction areas and the upwardly positioned metal lines and function to electrically connect them with each other.

While the contact plugs can be formed as a single layer, they may be formed to have a multi-layered structure depending upon the manufacturing processes of a semiconductor device. As the integration level of a semiconductor device increases, an aspect ratio of contact holes increases. In this regard, when the contact plugs are formed to have the multi-layered structure, it is difficult to properly form a conductive layer for contact plugs. For example, if the aspect ratio of the contact holes increases, since the upper ends of the contact holes are likely to be closed before the contact holes are completely filled to the bottoms thereof, voids may be formed in the contact plugs.

If voids are formed in the contact plugs, the insides of the contact plugs can be adversely influenced by a subsequently conducted etching process, and the voids can serve as a factor which increases resistance, whereby the reliability of a semiconductor device can be degraded.

### SUMMARY OF THE INVENTION

Embodiments of the present invention are directed to the contact plugs of a semiconductor device in which first contact plugs are first formed in a first interlayer dielectric, and after forming a second interlayer dielectric on the first interlayer dielectric including the first contact plugs, second contact plugs are formed in the second interlayer dielectric to come into contact with the first contact plugs, thereby preventing voids from being formed in contact plugs, and a method for forming the same.

Further, the embodiments of the present invention are directed to the contact plugs of a semiconductor device in which first contact plugs and second contact plugs are formed to have different widths, thereby securing an alignment margin, and a method for forming the same.

In one aspect, contact plugs of a semiconductor device comprises first contact plugs having an elliptical sectional shape, and second contact plugs formed on the first contact plugs and having the sectional shape of a circle. A diameter of the second contact plugs is greater than a length of a minor axis of the first contact plugs.

In another aspect of the present invention, contact plugs of a semiconductor device comprises first contact plugs having an elliptical sectional shape, and second contact plugs formed on the first contact plugs and having an elliptical sectional shape which has a major axis perpendicular to a major axis of the first contact plugs.

In yet another aspect of the present invention, a method for forming contact plugs of a semiconductor device comprises the steps of preparing a semiconductor substrate having a first interlayer dielectric formed thereon, defining a source contact hole and first drain contact holes in the first interlayer dielectric, filling a first conductive layer in the source contact hole and the first drain contact holes, forming a second interlayer dielectric on the first interlayer dielectric and the first conductive layer, etching the second interlayer dielectric formed on the first conductive layer and thereby defining second drain contact holes, and filling a second conductive layer in the second drain contact holes.

The source contact hole is defined in the form of a line, and the first drain contact holes are defined to have an elliptical sectional shape. A distance between the first drain contact holes is about 30 to 50 nm.

The second drain contact holes are defined to have a circular sectional shape. A diameter of the second drain contact holes is greater than a length of a minor axis of the first drain contact holes.

The step of defining the second drain contact holes comprises the step of exposing the first drain contact plugs and portions of the first interlayer dielectric, and etching the exposed portions of the first interlayer dielectric by conducting an over-etching process. The first conductive layer and the second conductive layer are formed of tungsten (W).

Before the step of filling the first conductive layer, the method further comprises the step of forming spacers on sidewalls of the source contact hole and the first drain contact holes.

Before the step of filling the second conductive layer, the method further comprises the step of forming spacers on sidewalls of second drain contact holes. The spacers comprise a nitride layer.

Before the step of filling the first conductive layer, the method further comprises the step of forming a barrier layer on surfaces of the source contact hole and the first drain contact holes.

Before the step of filling the second conductive layer, the method further comprises the step of forming a barrier layer on surfaces of the second drain contact holes. The barrier layer comprises a stack of a Ti layer and a TiN layer.

In a still further aspect, a method for forming contact plugs of a semiconductor device comprises the steps of preparing a semiconductor substrate having a first interlayer dielectric formed thereon, defining first contact holes having an elliptical sectional shape, in the first interlayer dielectric, filling a first conductive layer in the first contact holes, forming a second interlayer dielectric on the first interlayer dielectric and the first conductive layer, etching portions of the second interlayer dielectric on the first contact holes and thereby defining second contact holes having a circular sectional shape, and filling a second conductive layer in the second contact holes. A diameter of the circle is greater than a length of a minor axis of the ellipse.

### BRIEF DESCRIPTION OF THE DRAWINGS is

FIGS. 1A through 1D are plan views illustrating a method for forming the contact plugs of a semiconductor device in accordance with an embodiment of the present invention.

FIGS. 2A through 2D are sectional views explaining the method for forming the contact plugs of a semiconductor device in accordance with the embodiment of the present invention.

### DESCRIPTION OF SPECIFIC EMBODIMENTS

Reference will now be made in greater detail to specific embodiments of the invention, examples of which are illustrated in the attached drawings. It is to be noted that the present invention must not be construed as being limited to the following embodiments and can be realized in a variety of ways. The embodiments are provided to make the disclosure of the present invention complete and to allow those persons having ordinary knowledge in the art to better understand the scope of the present invention.

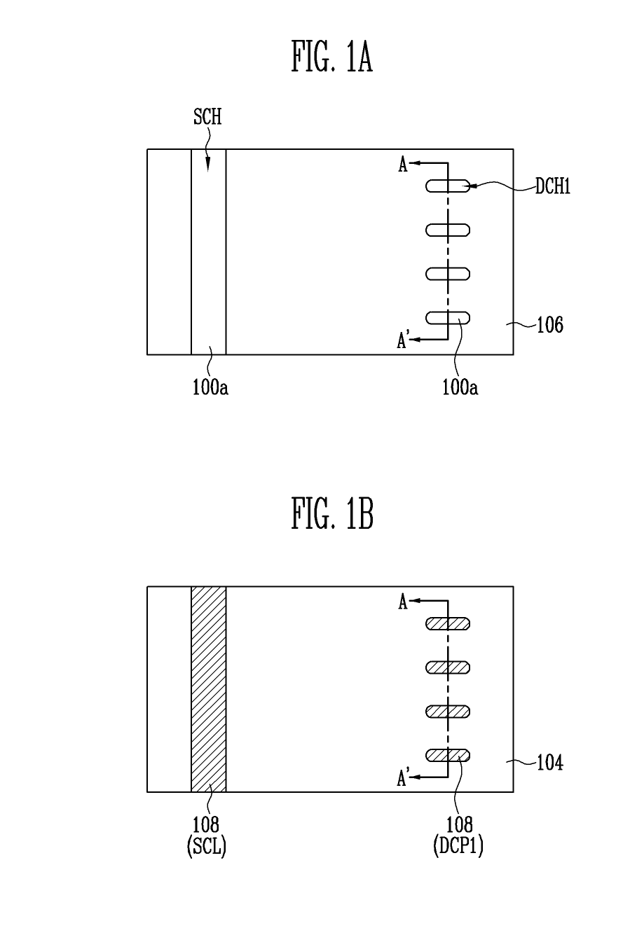

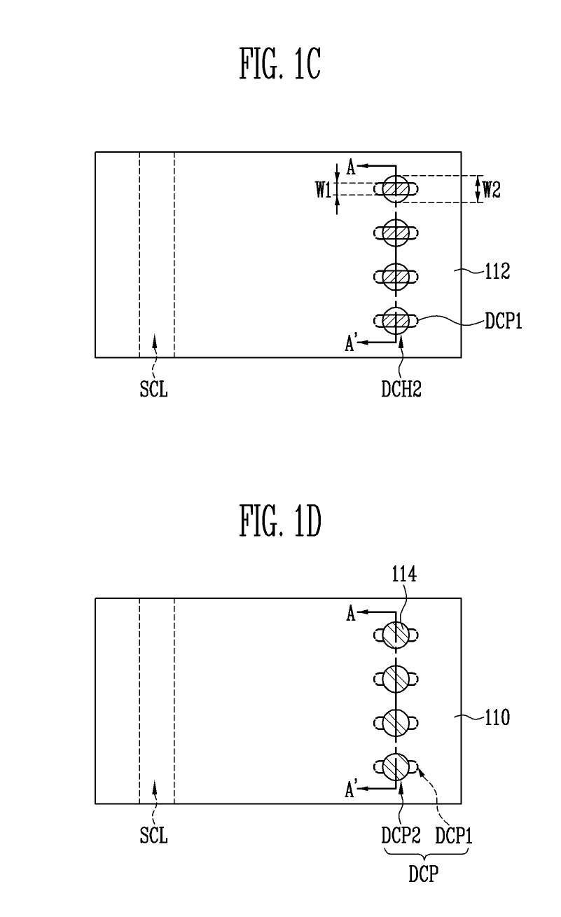

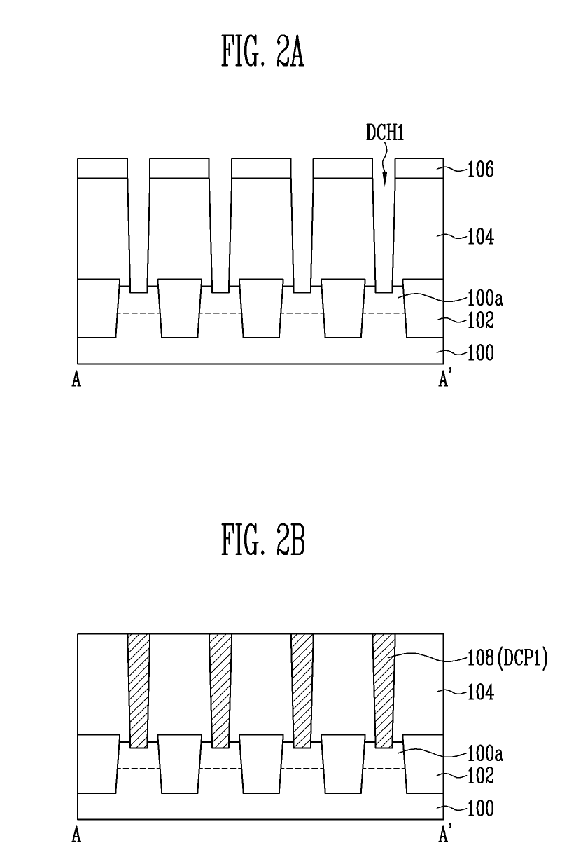

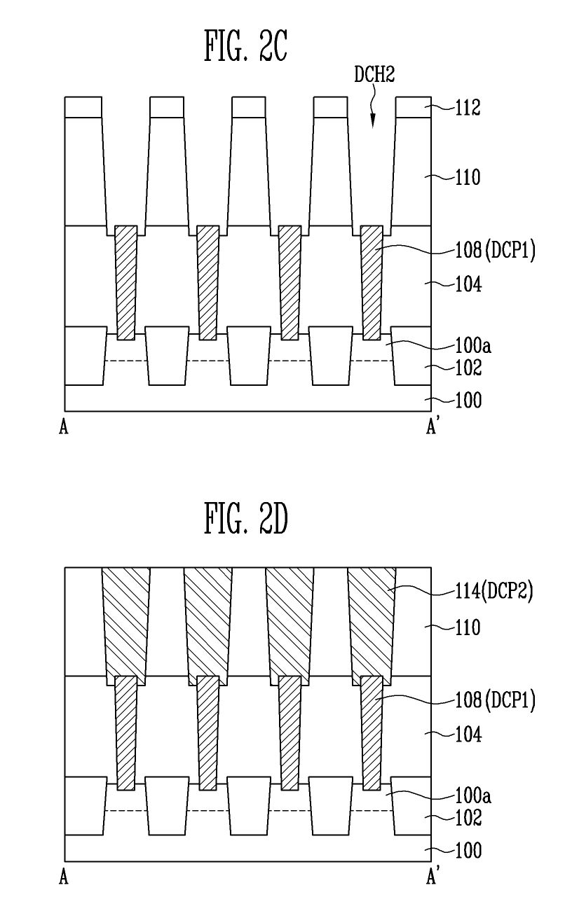

FIGS. 1A through 1D are plan views explaining a method for forming the contact plugs of a semiconductor device in accordance with an embodiment of the present invention, and FIGS. 2A through 2D are sectional views taken along the lines A-A′ of FIGS. 1A through 1D, explaining the method for forming the contact plugs of a semiconductor device in accordance with the embodiment of the present invention.

Referring to FIGS. 1A and 2A, a flash memory device will be described by way of example.

A semiconductor substrate 100 in which an un-illustrated lower structure (for example, including a plurality of word lines and select lines) is formed and which includes junction areas 100a, is prepared. In the case of a flash memory device, active regions in a memory cell zone are formed to constitute a plurality of strings, and an isolation layer 102 is formed between strings to electrically insulate the active regions of the strings from each other. Also, a plurality of word lines (not shown) are connected in series to the respective strings, and select lines (not shown) for transmitting a driving voltage are formed on both ends of the word lines. A source select line (SSL) (not shown) is formed on the source terminals of the word lines, and a drain select line (DSL) (not shown) is formed on the drain terminals of the word lines.

A first interlayer dielectric 104 is formed on the semiconductor substrate 100 including the above-described lower structure. A first photoresist pattern 106, which is open in the area of a source contact hole SCH and the areas of first drain contact holes DCH1, is formed on the first interlayer dielectric 104. For example, the first interlayer dielectric 104 can comprise an oxide layer and can have a thickness of 2,000˜3,500 Å.

By etching the first interlayer dielectric 104 using the first photoresist pattern 106, the portions of the junction areas 100a, which are formed on the semiconductor substrate 100, are exposed. Therefore, the source contact hole SCH and the first drain contact holes DCH1 are defined. At this time, it is preferred that the source contact hole SCH be defined in the form of a line and the first drain contact holes DCH1 be defined to have an elliptical sectional shape in which a major axis and a minor axis have different lengths as a matter of course. In particular, while the distance between two first drain contact holes DCH1 adjoining each other may vary depending upon a semiconductor device, in order to prevent the occurrence of a bridge, the distance can be set to be greater than 30 nm (for example, to 30 to 50 nm). Further, un-illustrated spacers (for example, comprising a nitride layer) can be formed on the sidewalls of the source contact hole SCH and the first drain contact holes DCH1 so that a margin for avoiding the occurrence of a bridge can be additionally secured. At this time, the spacers can be formed to a thickness of about 40 to 70 Å.

Referring to FIGS. 1B and 2B, the first photoresist pattern 106 is removed, and a first conductive layer 108 for contact plugs is filled in the source contact hole SCH and the first drain contact holes DCH1. The first conductive layer 108 can be formed of polysilicon or tungsten (W). Preferably, the first conductive layer 108 is formed of tungsten because tungsten has low resistance and a gap-fill process can be easily conducted for tungsten.

The first conductive layer 108 for contact plugs is formed on the first interlayer dielectric 104, preferably, to a sufficient thickness, such that the source contact hole SCH and the first drain contact holes DCH1 can be completely filled with the first conductive layer 108. Then, by conducting a planarization process (for example, a chemical mechanical polishing (CMP) process) until the upper end of the first interlayer dielectric 104 is exposed, a source contact line SCL and first drain contact plugs DCP1 are formed.

Before forming the first conductive layer 108, a barrier layer (not shown) for preventing diffusion and improving an adhesion characteristic can be formed on the surfaces of the source contact hole SCH and the first drain contact holes DCH1. At this time, the barrier layer can be formed by stacking a Ti layer and a TiN layer.

Referring to FIGS. 1C and 2C, a second interlayer dielectric 110 is formed on the first interlayer dielectric 104 and the first conductive layer 108. The second interlayer dielectric 110 can comprise an oxide layer and can be formed to a thickness of 2,000˜4,000 Å.

A second photoresist pattern 112, which is open in the areas of second drain contact holes DCH2, is formed on the second interlayer dielectric 110. By etching the second interlayer dielectric 110 using the second photoresist pattern 112, second drain contact holes DCH2 are defined.

Specifically, it is preferred that the second drain contact holes DCH2 be defined to have a circular sectional shape. At this time, the second drain contact holes DCH2 are defined in a manner such that the diameter W2 of the second drain contact holes DCH2 is greater than the length W1 of the minor axis of the first drain contact plugs DCP1 which are formed to have an elliptical sectional shape, and such that the second drain contact holes DCH2 adjoining each other do not communicate with each other. Alternatively, the second drain contact holes DCH2 can be defined to have an elliptical sectional shape which has a major axis perpendicular to the major axis of the first drain contact plugs DCP1. In this case, it may be difficult to secure a margin in the distance between adjoining second drain contact holes DCH2. For this reason, it is preferred that the second drain contact holes DCH2 be defined to have a circular sectional shape as described above.

When conducting an etching process to define the second drain contact holes DCH2, it is preferred that an over-etching process be conducted for the exposed portions of the first interlayer dielectric 104 such that the first drain contact plugs DCP1 can be exposed to a sufficient extent. For example, the over-etching process can be conducted such that the lower ends of the second drain contact holes DCH2 are positioned at a depth of 200˜1,000 Å when measured from the upper ends of the first drain contact plugs DCP1.

Meanwhile, spacers (not shown) for preventing the diffusion of and improving the adhesion characteristic of a conductive layer to be subsequently formed can be formed on the sidewalls of the second drain contact holes DCH2. For example, the spacers can comprise a nitride layer. A nitride layer is formed on the surfaces of the second drain contact holes DCH2 to a thickness of about 30 to 80 Å. Then, an etching process is conducted such that the nitride layer only remains on the sidewalls of the second drain contact holes DCH2. At this time, it is preferred that the etching process be conducted as a dry etching process and under a pressure of about 5 to 20 mtorr so as to reduce the loss of the spacers which remain on the sidewalls of the second drain contact holes DCH2.

Referring to FIGS. 1D and 2D, the second photoresist pattern 112 is removed, and a second conductive layer 114 is filled in the second drain contact holes DCH2. The second conductive layer 114 is formed on the second interlayer dielectric 110 having the second drain contact holes DCH2 defined therein and on portions of the first interlayer dielectric 104 and the first drain contact plugs DCP1 which are exposed through the second drain contact holes DCH2. Thereupon, a planarization process (for example, a CMP process) is conducted until the upper end of the second interlayer dielectric 110 is exposed.

Also, before forming the second conductive layer 114, a barrier layer can be formed on the surfaces of the second drain contact holes DCH2 by stacking a Ti layer and a TiN layer.

In this way, second drain contact plugs DCP2, which are electrically connected with the first drain contact plugs DCP1, are formed. As a consequence, drain contact plugs DCP can be formed to have the stack structure of the first drain contact plugs DCP1 and the second drain contact plugs DCP2.

Therefore, in the present invention, when forming contact plugs having an increased aspect ratio, the contact plugs can be formed to have a multi-layered structure, whereby it is possible to prevent voids from being formed in the contact plugs. In particular, when forming the contact plugs to have the multi-layered structure, by overlapping different sectional shapes (for example, of an ellipse and a circle), an alignment margin can be secured. That is to say, second contact plugs having a circular sectional shape can be formed on the first contact plugs having an elliptical sectional shape, or vice versa. At this time, it is preferred that the diameter of the circle be greater than the length of the minor axis of the ellipse.

Accordingly, the manufacturing yield can be increased in the manufacture of a semiconductor device, and since it is possible to prevent the electrical characteristics of a semiconductor device from being degraded, the reliability of the semiconductor device can be improved.

As is apparent from the above description, in the embodiments of the present invention, first contact is plugs are first formed in a first interlayer dielectric, and after forming a second interlayer dielectric on the first interlayer dielectric including the first contact plugs, second contact plugs are formed in the second interlayer dielectric to come into contact with the first contact plugs. Therefore, it is possible to prevent voids from being produced in contact plugs, whereby the contact plugs can be prevented from being damaged. Also, in the present invention, because the first contact plugs and the second contact plugs are formed to have different widths, an alignment margin can be secured. As a consequence, even when an aspect ratio increases, the contact plugs can be easily formed, whereby it is possible to prevent the electrical characteristics of a semiconductor device from being deteriorated, and the manufacturing yield and the reliability of the semiconductor device can be increased and improved.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor device having a plurality of contact plugs, said device comprising:
a plurality of first contact plugs having an elliptical sectional shape; and
a plurality of second contact plugs, each of said second contact plugs being located on a respective first contact plug and having a circular sectional shape.

2. The device according to claim 1, wherein a diameter of each second contact plug is greater than a length of a minor axis of each respective first contact plug.

3. A semiconductor device having a plurality of contact plugs, said device comprising:
a plurality of first contact plugs having an elliptical sectional shape; and
a plurality of second contact plugs, each of said second contact plugs being located on a respective first contact plug and having an elliptical sectional shape which has a major axis perpendicular to a major axis of the respective first contact plug.

4. A method for forming contact plugs of a semiconductor device, comprising the steps of:
preparing a semiconductor substrate having a first interlayer dielectric formed thereon;
forming a source contact hole and a plurality of first drain contact holes in the first interlayer dielectric;
filling a first conductive layer in the source contact hole and each of the first drain contact holes;
forming a second interlayer dielectric on the first interlayer dielectric and the first conductive layer;
etching the second interlayer dielectric formed on the first conductive layer and thereby defining second drain contact holes; and
filling a second conductive layer in the second drain contact holes.

5. The method according to claim 4, wherein the source contact hole is defined in the form of a line, and each of the first drain contact holes are defined to have an elliptical sectional shape.

6. The method according to claim 4, wherein a distance between the first drain contact holes is about 30 to 50 nm.

7. The method according to claim 4, wherein the second drain contact holes are defined to have a circular sectional shape.

8. The method according to claim 7, wherein a diameter of each of the second drain contact holes is greater than a length of a minor axis of the respective first drain contact holes.

9. The method according to claim 4, wherein the step of defining the second drain contact holes comprises the step of:
exposing the first drain contact plugs and portions of the first interlayer dielectric; and
etching the exposed portions of the first interlayer dielectric by conducting an over-etching process.

10. The method according to claim 4, wherein the first conductive layer and the second conductive layer are formed of tungsten (W).

11. The method according to claim 4, wherein, before the step of filling the first conductive layer, the method further comprises the step of:
forming spacers on sidewalls of the source contact hole and the first drain contact holes.

12. The method according to claim 11t wherein the spacers comprise a nitride layer.

13. The method according to claim 4, wherein, before the step of filling the second conductive layer, the method further comprises the step of:
forming spacers on sidewalls of second drain contact holes.

14. The method according to claim 13, wherein the spacers comprise a nitride layer.

15. The method according to claim 4, wherein, before the step of filling the first conductive layer, the method further comprises the step of:
forming a barrier layer on surfaces of the source contact hole and the first drain contact holes.

16. The method according to claim 15, wherein the barrier layer comprises a stack of a Ti layer and a TiN layer.

17. The method according to claim 4, wherein, before the step of filling the second conductive layer, the method further comprises the step of:
forming a barrier layer on surfaces of the second drain contact holes.

18. The method according to claim 17, wherein the barrier layer comprises a stack of a Ti layer and a TiN layer.

19. A method for forming contact plugs of a semiconductor device, comprising the steps of:
preparing a semiconductor substrate having a first interlayer dielectric formed thereon;
forming a plurality of first contact holes having an elliptical sectional shape, in the first interlayer dielectric;
filling a first conductive layer in the first contact holes;
forming a second interlayer dielectric on the first interlayer dielectric and the first conductive layer;
etching portions of the second interlayer dielectric on the first contact holes and thereby defining second contact holes having a circular sectional shape; and
filling a second conductive layer in the second contact holes.

20. The method according to claim 19, wherein a diameter of the circle is greater than a length of a minor axis of the ellipse.
